(19) United States
(12) Patent Application Publication
(10) Pub. No.: US 2018/0074106 A1
(43) Pub. Date: Mar. 15, 2018

(54) APPARATUS AND METHOD FOR LOCATING A DATA CABLE

(71) Applicant: LENOVO Enterprise Solutions (Singapore) PTE. LTD., New Tech Park (SG)

(72) Inventors: HAI HANG WANG, ShangHai (CN); BO CHENG, ShangHai (CN); DING KANG, MinHang District (CN); JING CHEN, Shanghai (CN); YACHENG ZHU, Shanghai (CN); YUAN WANG, Shanghai (CN)

(21) Appl. No.: 15/703,774

(22) Filed: Sep. 13, 2017

(30) Foreign Application Priority Data
Sep. 13, 2016 (CN) 201610822798.7

(51) Int. Cl. G01R 31/02; G01R 29/18

(52) U.S. Cl. CPC G01R 31/023; H04M 3/229; G01R 29/18

(57) ABSTRACT

An invention includes an apparatus for locating a data cable. The apparatus includes a first connector configured to connect to a first electronic device, and a second connector configured to connect to a second electronic device. The first connector and the second connector are configured to allow data transmission between the first connector and the second connector via the data cable, and each of the first connector and the second connector include a display device and is configured to generate a same identifier for display at the display device of each connector in order to locate the data cable.

### CROSS-REFERENCE TO RELATED APPLICATIONS

This patent application claims priority to Chinese Patent Application No. CN 201610822798.7 filed on Sep. 13, 2016 for Hai Hang Wang, et al., the entire contents of which are incorporated herein by reference for all purposes.

### FIELD

Embodiments of the present invention relate to an apparatus and method for locating a data cable.

### BACKGROUND

In the present day, network connectivity is critical both for businesses and for individuals. As a result, data centers are ubiquitous and constantly increasing in numbers.

When data centers are set up, large quantities of data cables are utilized to ensure that connections between data processing apparatus are properly set up. It should be appreciated that during the set-up process, the data cables need to be located such that appropriate connections can be carried out between the data processing apparatus. Moreover, during maintenance of the data center, the data cables also need to be located so that they can be replaced and/or upgraded.

Currently, adhesive tabs/strips may be used to locate the data cables, but loss of the tabs/strips from the data cables clearly leads to substantial issues with regard to locating the data cables. In addition, adhering the tabs/strips is also a laborious process.

Furthermore, a data cable tester may also be used to locate the data cables, but the use of the tester requires more than one person. In this regard, the requisite manpower to use the tester may not be available.

Finally, it may also be possible to use a universal meter to locate the data cables. However, the universal meter is only usable by trained users, and thus, the requisite personnel to use the universal meter may not be available.

### BRIEF SUMMARY

A first aspect of the invention is an apparatus for locating a data cable, the apparatus comprising:
a first connector configured to connect to a first electronic device; and
a second connector configured to connect to a second electronic device;
wherein the first connector and the second connector are configured to allow data transmission between the first connector and the second connector via the data cable, and each of the first connector and the second connector comprises a display device and is configured to generate a same identifier for display at the display device of each connector in order to locate the data cable.

A second aspect of the invention is a data cable, comprising:
an apparatus for locating a data cable, the apparatus having:
a first connector configured to connect to a first electronic device; and
a second connector configured to connect to a second electronic device;
wherein the first and second connectors are configured to allow data transmission between the first connector and the second connector via the data cable, and each of the first and second connectors is configured to generate a same identifier for display in order to locate the data cable.

A third aspect of the invention is a method of locating a data cable, the method comprising:
generating an identifier; and
displaying the identifier at both a first connector and a second connector, the first and second connectors being configured to connect to a first electronic device and a second electronic device respectively,
wherein the first and second connectors are configured to allow data transmission between the first connector and the second connector via the data cable, and each of the first and second connectors is configured to generate a same identifier for display in order to locate the data cable.

A fourth aspect of the present invention is a connector for locating a data cable, the connector comprising:
a first channel for transmitting data;
a second channel for receiving data;
a microcontroller configured for generating an identifier; and
at least one display device coupled to the microcontroller, the at least one display device being configured to indicate the identifier,
wherein the identifier is configured to be transmitted via the first channel, and indicated on the at least one display device upon positive verification of data received via the second channel.

Some optional features or steps of the present invention have been defined in the dependent claims.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 shows a possible embodiment of an apparatus of the present invention;

FIG. 2 shows a circuit diagram of a possible embodiment of a connector as shown in FIG. 1;

FIG. 3 shows a process flow of a possible embodiment of a method of the present invention; and

FIG. 4 shows a process flow of a possible embodiment of a method of a microcontroller unit (“MCU”) of the connector of FIG. 2.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, embodiments may take the form of a program product embodied in one or more computer readable storage devices storing machine readable code, computer readable code, and/or program code, referred hereafter as code. The storage devices may be tangible, non-transitory, and/or non-transmission. The storage devices may not embody signals. In a certain embodiment, the storage devices only employ signals for accessing code.

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that all or a portion of each block of the schematic flowchart diagrams and/or schematic block diagrams, and combinations of blocks in the schematic flowchart diagrams and/or schematic block diagrams, can be implemented by code. These code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a module, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

There are provided embodiments of an apparatus and method for locating a data cable (e.g. a network cable). The apparatus and method are able to provide users with a way to locate a data cable from a cluster of cables, possibly in a manner where only a single person is required to locate the data cable. It should be noted that minimal training is required for the user before using the apparatus and method.

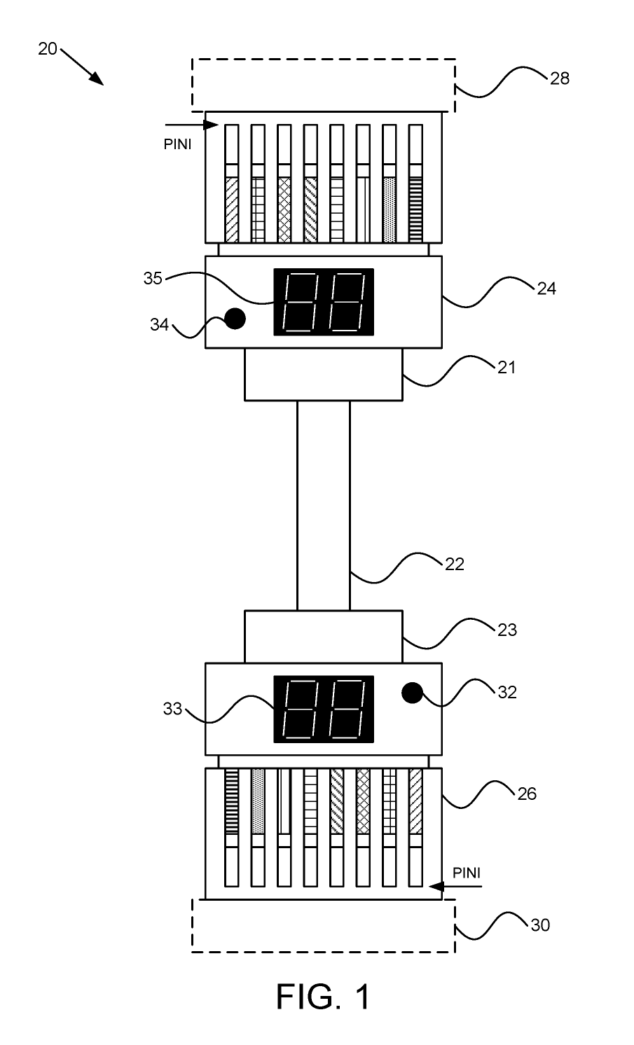

Referring to FIG. 1, there is provided an apparatus 20 for locating a data cable 22. The data cable 22 can include male RJ45 connectors at each end of the data cable 22. It should be appreciated that the data cable 22 can also include other male connectors, and may also include a fiber optic cable.

The apparatus 20 comprises a first connector 24 configured to connect to a first electronic device 28. The first electronic device 28 can be, for example, a data processing apparatus, a communications enabling apparatus, a data repository, and so forth. The apparatus 20 also comprises a second connector 26 configured to connect to a second electronic device 30. The second electronic device 30 can be, for example, a data processing apparatus, a communications enabling apparatus, a data repository, and so forth. Each of the first connector 24 and the second connector 26 includes a display device 35, 33 respectively. The display device 35, 33 can be, for example, a light-emitting diode (“LED”) display device, a liquid crystal display (“LCD”) display device, and so forth. It should be appreciated that the first connector 24 and the second connector 26 are identical, and further description will be of the connector 24/26 will be provided in a later portion of the description.

The first connector 24 is located at a first end 21 of the data cable 22, and the second connector 26 is located at a second opposite end 23 of the data cable 22. In one embodiment, RJ45 connectors at the ends 21, 23 of the data cable 22 can be coupled to the first connector 24 and the second connector 26 respectively. In another embodiment, the first connector 24 and the second connector 26 are integrated with the data cable 22.

In one embodiment, the apparatus 20 can also comprise a power source to power either or both of the first connector 24 and the second connector 26. Alternatively, current may be drawn via power lines from either or both of the first 28 and the second electronic devices 30.

In the apparatus 20, the first connector 24 and the second connector 26 are configured to allow data transmission from the first connector 24 to the second connector 26 via the data cable 22. When a user activates a switch 34, an identifier is generated randomly from the first connector 24, and upon a positive verification of the data transmission from the first connector 24 to the second connector 26 (or vice versa), each of the first connector 24 and the second connector 26 is configured to generate a same identifier for display at the display device 33, 35 of the first connector 24 and the second connector 26 in order to locate the data cable 22. Alternatively, the identifier can be automatically generated at pre-determined intervals such as, for example, every three seconds, every five seconds, every ten seconds and so forth.

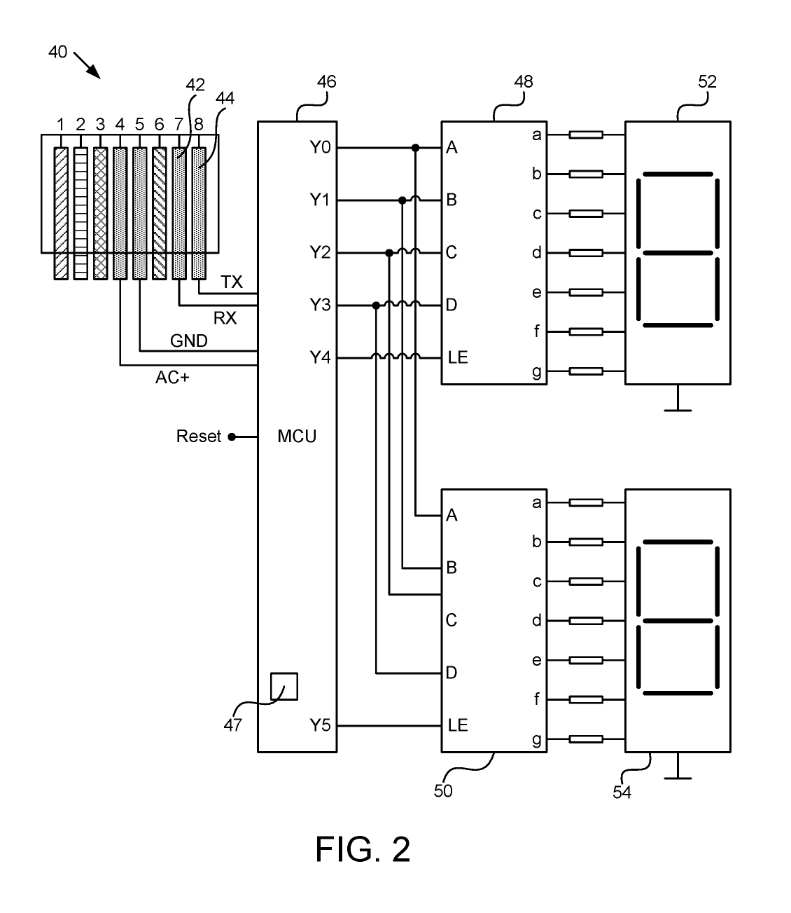

Referring to FIG. 2, there is shown a connector 40. It should be appreciated that the connector 40 is identical to the first connector 24 and the second connector 26. The connector 40 comprises a first channel 44 for transmitting data and a second channel 42 for receiving data. It should be appreciated that the first channel 44 and the second channel 42 can be discrete pins in a female connector which couples with an RJ45 male connector on a data cable 22.

The connector 40 can also include a microcontroller (“MCU”) 46 configured for generating an identifier, whereby the identifier can be a random identifier. The microcontroller 46 can be coupled to at least one display device 52, 54, via display device drivers 48, 50. The at least one display device 52, 54 can be, for example, an LED display device, an LCD display device, and so forth. The at least one display device 52, 54 is configured to indicate the identifier.

In one embodiment, the connector 40 can also comprise a power source to power the connector 40. Alternatively, current may be drawn via power lines from an electronic device coupled to the connector 40.

In the connector 40, data is received via the first channel 44 via the data cable 22. When an identifier is generated randomly from the connector 40 by activating switch 47, upon a positive verification of the data transmission from the other connector 40 at another end of the data cable 22, each of the connectors 40 is configured to generate an identical identifier for display at the at least one display device 52, 54 of the connector 40 and the other connector 40 in order to locate the data cable 22.

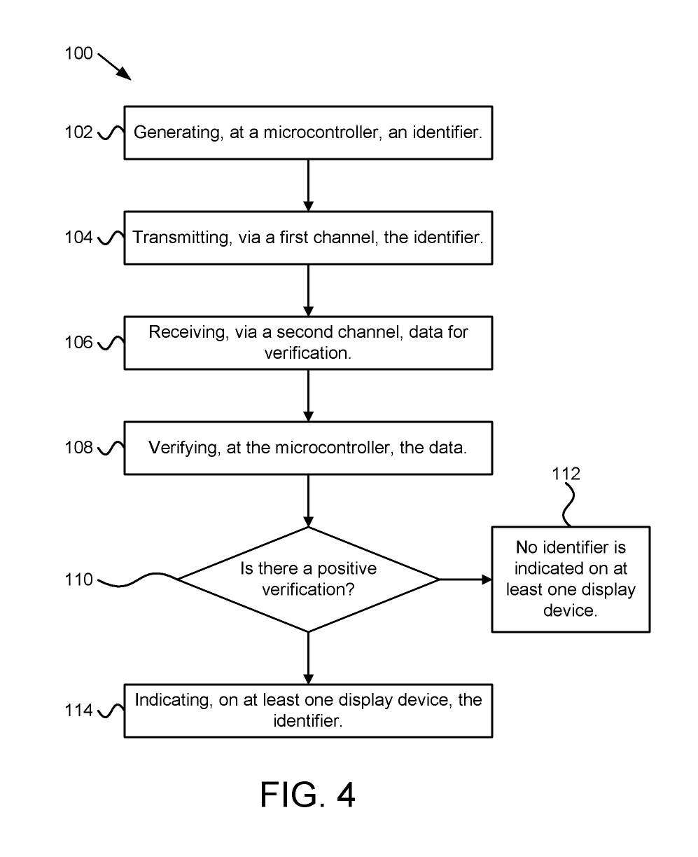

Referring to FIG. 4, there is shown a data processor implemented method 100 for locating a data cable, as carried out by the microcontroller 46. The method 100 comprises generating, at a microcontroller 46, an identifier (102). The identifier can be a random identifier. Then, the method 100 comprises transmitting, via a first channel 44, the identifier (104) and receiving, via a second channel 42, data for verification (106).

Subsequently, there is verification, at the microcontroller 46, of the data (108) to determine if there is a positive verification (110). It should be appreciated that positive verification occurs when the data received via the second channel 42 includes the identifier transmitted via the first channel 44. Where there is no positive verification, no identifier is indicated on the at least one display device 52, 54 (112).

Where there is positive verification, the identifier is indicated on at least one display device 52, 54 (114).

It should be appreciated that the method 100 can be carried out by a program of computer readable instructions residing in a non-transitory computer readable storage medium, whether in a transient or a permanent state of storage.

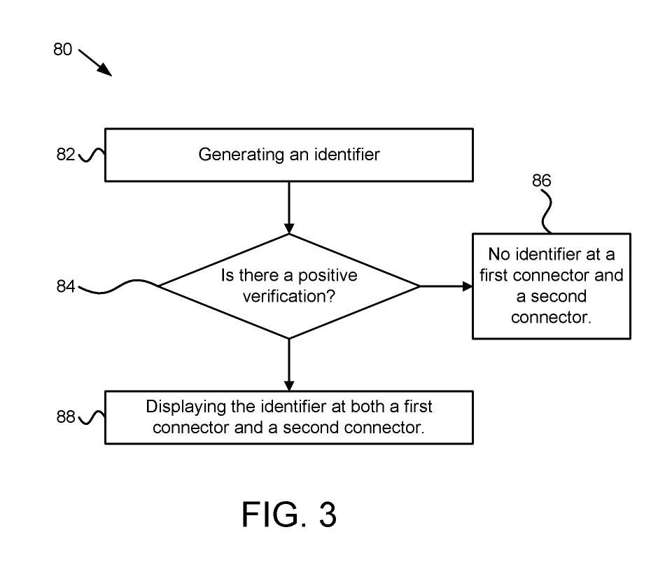

Referring to FIG. 3, there is provided a method 80 for locating a data cable. The method 80 can be carried our using the apparatus 20, or can be carried out using other devices. For the sake of illustration, the method 80 will be described in conjunction with use of the apparatus 20.

The method 80 comprises generating an identifier (82), whereby the identifier can be generated randomly. Subsequently, a determination is made if there is a positive verification (84), whereby a positive verification of the data transmission from a first connector 24 to a second connector 26 occurs if the second connector 26 displays the same identifier. Where there is no positive verification, no identifier is displayed on the first connector 24 and the second connector 26 (86).

Where there is a positive verification, the identifier is displayed at both the first connector 24 and the second connector 26 (88).

It should be appreciated that the apparatus 20 and the method 80 are able to be used to locate a data cable in a convenient and quick manner.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a first connector configured to connect to a first electronic device; and;
a second connector configured to connect to a second electronic device;
wherein the first and second connectors are configured to allow data transmission between the first connector and the second connector via a data cable, and each of the first connector and the second connector comprises a display device and is configured to generate a same identifier for display at the display device of each connector in order to locate the data cable.

2. The apparatus of claim 1, wherein the first connector is located at a first end of the data cable, and the second connector is located at a second end of the data cable opposite the first end.

3. The apparatus of claim 2, wherein the first and second connectors are configured to be coupled to the data cable.

4. The apparatus of claim 2, wherein the first and second connectors are integrated with the data cable.

5. The apparatus of claim 1, further comprising a power source to power one or more of the first connector and the second connector.

6. The apparatus of claim 1, further comprising one or more power lines to draw current from one or more of the first electronic device and the second electronic device.

7. The apparatus of claim 1, wherein the display device comprises a light-emitting diode (“LED”) display device.

8. The apparatus of claim 1, wherein the display device comprises a liquid crystal display (“LCD”) display device.

9. The apparatus of claim 1, wherein a positive verification of the data transmission from the first connector to the second connector occurs if the second connector displays the same identifier.

10. The apparatus of claim 1, wherein the identifier is generated randomly.

11. A data cable comprising:
an apparatus for locating a data cable, the apparatus having:
a first connector configured to connect to a first electronic device; and
a second connector configured to connect to a second electronic device;
wherein the first and second connectors are configured to allow data transmission between the first connector and the second connector via the data cable, and each of the first and second connectors is configured to generate a same identifier for display in order to locate the data cable.

12. The data cable of claim 11, wherein the first connector is located at a first end of the data cable, wherein the second connector is located at a second end of the data cable opposite the first end.

13. The data cable of claim 12, wherein the first and second connectors are detachable from the data cable.

14. The data cable of claim 11, further comprising a power source to power either or both of the first and second connectors.

15. The data cable of claim 11, further comprising one or more power lines to draw current from either or both of the first and second electronic devices.

16. The data cable of claim 11, wherein a positive verification of the data transmission from the first connector to the second connector occurs if the second connector displays the same identifier.

17. The apparatus of claim 11, wherein the first connector and the second connector each comprise an electronic display that displays the identifier.

18. A method comprising:
generating an identifier; and
displaying the identifier at both a first connector and a second connector, the first and second connectors being configured to connect to a first electronic device and a second electronic device respectively,
wherein the first and second connectors are configured to allow data transmission between the first connector and the second connector via a data cable, and each of the first and second connectors is configured to generate a same identifier for display in order to locate the data cable.

19. The method of claim 18, wherein a positive verification of the data transmission from the first connector to the second connector occurs if the second connector displays the same identifier.

20. The method of claim 18, wherein the identifier is generated randomly.
